(19) United States
(12) Patent Application Publication
(10) Pub. No.: US 2023/0361017 A1
(43) Pub. Date: Nov. 9, 2023

(54) PACKAGE AND METHOD OF FABRICATING THE SAME

(71) Applicant: SAMSUNG ELECTRONICS CO., LTD., Suwon-si (KR)

(72) Inventors: HYEONJEONG HWANG, Suwon-si (KR); INHYUNG SONG, Suwon-s (KR); HYEONSEOK LEE, Suwon-si (KR)

(73) Assignee: SAMSUNG ELECTRONICS CO., LTD., Suwon-s (KR)

(21) Appl. No.: 18/119,705

(22) Filed: Mar. 9, 2023

(30) Foreign Application Priority Data
May 8, 2022 (KR) 10-2022-0096376

(51) Int. Cl. H01L 23/498; H01L 23/00; H01L 23/544; H01L 21/56; H01L 21/48; H01L 23/31; H01L 25/16; H10B 80/00

(52) U.S. Cl. CPC H01L 23/49838; H01L 24/16; H01L 24/32; H01L 24/73; H01L 23/544; H01L 21/565; H01L 21/486; H01L 21/4853; H01L 23/49816; H01L 23/49833; H01L 23/3128; H01L 23/3135; H01L 25/162; H01L 25/165; H10B 80/00; H01L 2224/16227; H01L 2224/16238; H01L 2224/32225; H01L 2224/73204; H01L 2223/54486; H01L 2924/1533; H01L 2924/15165

(57) ABSTRACT

Disclosed are packages and their fabrication methods. The package includes: a lower substrate with an upper pad; a lower chip on the lower substrate; a mold layer on the lower chip and the lower substrate; a post extending through the mold layer and provided on the upper pad around the lower chip, the post having a diameter less than a diameter of the upper pad; and an upper substrate on the post and the mold layer, the upper substrate including a lower pad having a diameter greater than the diameter of the post.

### CROSS-REFERENCE TO RELATED APPLICATION

This application claims priority to Korean Patent Application No. 10-2022-0096376, filed on Aug. 2, 2022, in the Korean Intellectual Property Office, the disclosure of which is incorporated by reference herein in its entirety.

### BACKGROUND

The present disclosure relates to a package and a method of fabricating the same, and more particularly, to a fan-out package and a method of fabricating the same.

A size of semiconductor chip becomes smaller as integration of the semiconductor chip increases. However, intervals between bumps on the semiconductor chip should comply with international standards provided by the Joint Electronic Device Engineering Council (JEDEC), an international electronics standardization organization. It may be difficult to bond a desired number of the bumps to the semiconductor chip. In addition, as the size of the semiconductor chip becomes reduced, it may be hard to handle and test the semiconductor chip.

### SUMMARY

Some example embodiments provide a package capable of suppressing cracks of an upper substrate on a lower chip.

According to some embodiments, a package includes: a lower substrate including an upper pad; a lower chip on the lower substrate; a mold layer on the lower chip and the lower substrate; a post extending through the mold layer and provided on the upper pad around the lower chip, the post having a diameter less than a diameter of the upper pad; and an upper substrate on the post and the mold layer, the upper substrate including a lower pad having a diameter greater than the diameter of the post.

According to some embodiments, a package includes: a lower substrate including an upper pad; a lower chip on the lower substrate; a post on the upper pad, the post having a diameter less than a diameter of the upper pad; and an upper substrate on the post, the upper substrate including a lower pad having a diameter greater than the diameter of the post. The upper pad, the post, and the lower pad are connected to form an “I” shape when viewed in vertical section.

According to some embodiments, a method of fabricating a package, includes: providing a lower substrate having upper pads on a dummy substrate, the upper pads each having a diameter; providing posts on the upper pads, the posts each having a diameter less than the diameter of the upper pads; providing a lower chip on the lower substrate between the posts; providing a mold layer on the lower substrate that selectively exposes top surfaces of the posts; and providing an upper substrate that is on the posts and the mold layer, and has lower pads, each having a diameter greater than the diameter of the posts.

### BRIEF DESCRIPTION OF DRAWINGS

The above and other aspects and features will be more apparent from the following description of example embodiments, taken in conjunction with the accompanying drawings, in which:

FIG. 1 illustrates a plan view showing an example of a package according to some example embodiments.

FIG. 2 illustrates a cross-sectional view taken along line I-I′ of FIG. 1 according to some example embodiments.

FIGS. 3A and 3B illustrate plan views showing examples of warpage control patterns according to some example embodiments.

FIG. 4 illustrates a flow chart showing a method of fabricating a package according to some example embodiments.

FIGS. 5 to 11 illustrate cross-sectional views showing a method of fabricating a package according to some example embodiments.

FIG. 12 illustrates a flow chart showing an example of a lower substrate formation operation according to some example embodiments.

FIG. 13 illustrates a flow chart showing an example of an upper substrate formation operation according to some example embodiments.

FIG. 14 illustrates a cross-sectional view showing an example of a package according to some example embodiments.

FIG. 15 illustrates a cross-sectional view showing an example of a package according to example embodiments.

FIG. 16 illustrates a cross-sectional view showing an example of a package according to example embodiments.

FIG. 17 illustrates a cross-sectional view showing an example of a first upper pad, a first upper bump, and a solder according to some example embodiments.

### DETAILED DESCRIPTION

Example embodiments will be described more fully with reference to the accompanying drawings, in which example embodiments are shown. Embodiments described herein are provided as examples, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

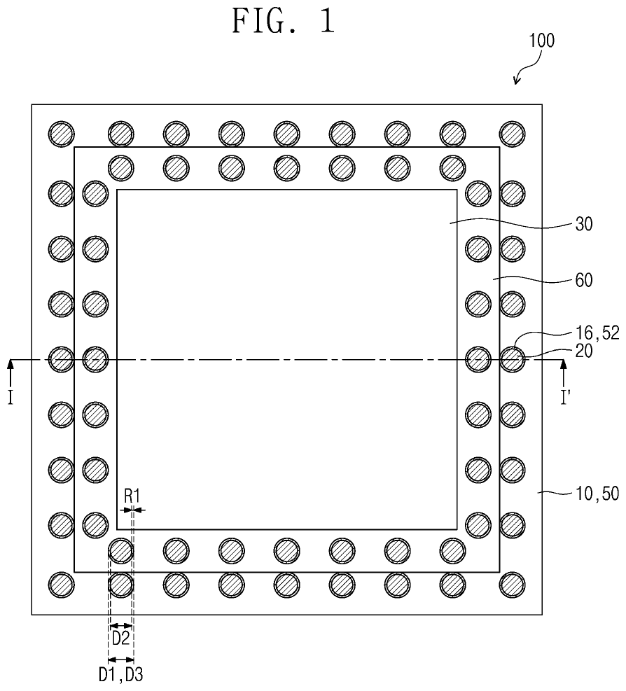

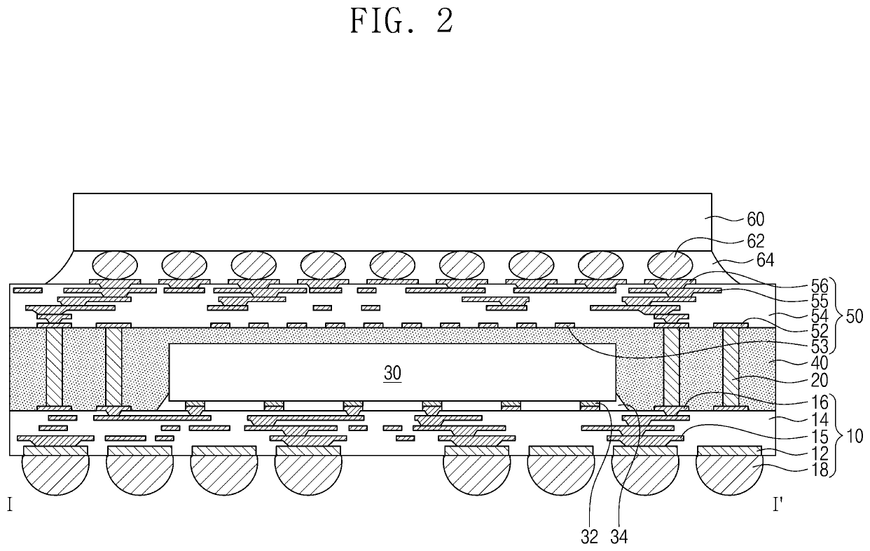

FIG. 1 shows an example of a package 100 according to some example embodiments. FIG. 2 shows a cross-sectional view taken along line I-I′ of FIG. 1.

Referring to FIGS. 1 and 2, a package 100 may include a fan-out package. According to an example embodiment, the package 100 may include a lower substrate 10, posts 20, a lower chip 30, a mold layer 40, an upper substrate 50, and an upper package 60.

The lower substrate 10 may be provided below the posts 20 and the lower chip 30. For example, the lower substrate 10 may have a height ranging from about 80 μm to about 100 μm. The lower substrate 10 may include a redistribution substrate. According to an example embodiment, the lower substrate 10 may include first lower pads 12, a lower dielectric layer 14, a lower redistribution layer 15, first upper pads 16, and lower bumps 18.

The first lower pads 12 may be provided on a bottom surface of the lower dielectric layer 14. The first lower pads 12 may connect the lower redistribution layer 15 to the lower bumps 18. The first lower pad 12 may have the same diameter as that of the lower bump 18. The first lower pads 12 may include metal, such as gold (Au), aluminum (Al), copper (Cu), or silver (Ag), but example embodiments are not limited thereto.

The lower dielectric layer 14 may be provided on the first lower pads 12. The bottom surface of the lower dielectric layer 14 may be coplanar with those of the first lower pads 12. The lower dielectric layer 14 may be provided below the first upper pads 16. For example, the lower dielectric layer 14 may include a photo-imageable dielectric (PID) layer.

The lower redistribution layer 15 may be provided in the lower dielectric layer 14. The lower redistribution layer 15 and the lower dielectric layer 14 may be alternately stacked. The lower redistribution layer 15 may connect the first lower pads 12 to the first upper pads 16. For example, the lower redistribution layer 15 may have a “T” shape when viewed in vertical section. The lower redistribution layer 15 may include copper, but example embodiments are not limited thereto.

The first upper pads 16 may be provided on the lower dielectric layer 14 and the lower redistribution layer 15. The first upper pads 16 may be wider than the posts 20. When viewed in vertical section, the first upper pads 16 may each have the same shape as that of the lower redistribution layer 15. For example, the first upper pads 16 may have “T” shapes that correspond to the “T” shapes of the lower redistribution layer 15. The first upper pads 16 may each have a first diameter D1 ranging from about 80 μm to about 450 μm.

The lower bumps 18 may be provided below the first lower pads 12. For example, the lower bumps 18 may be connected to an external printed circuit board. The lower bumps 18 may include gold (Au), aluminum (Al), solder, copper (Cu), or silver (Ag), but example embodiments are not limited thereto.

The posts 20 may be provided on an edge of the lower substrate 10. The posts 20 may be disposed on the first upper pads 16 around the lower chip 30. The posts 20 may be connected, through the lower substrate 10, to the lower chip 30. The posts 20 may each have a height greater than the lower chip 30. The posts 20 may each be taller than the lower chip 30. The posts 20 may include copper (Cu), but example embodiments are not limited thereto. When viewed in plan, the post 20 may be narrower than the first upper pad 16. According to an example embodiment, each of the posts 20 may have a second diameter D2 less than the first diameter D1 of each first upper pads 16. For example, the second diameter D2 of each post 20 may range from about 70 μm to about 250 μm.

The lower chip 30 may be provided on a center of the lower substrate 10. The lower chip 30 may be disposed between the posts 20. The lower chip 30 may be provided on the first upper pads 16. The lower chip 30 may be connected, through first upper bumps 32, to the first upper pads 16 of the lower substrate 10. The lower chip 30 may have a tetragonal shape when viewed in plan. The first upper bumps 32 may be provided in a first under-fill layer 34. For example, the lower chip 30 may include an application processor chip. The lower chip 30 may have a top surface lower than those of the posts 20. For example, the lower chip 30 may have a height of about 200 μm.

The mold layer 40 may be provided on the lower chip 30 and the lower substrate 10. The mold layer 40 may be provided between the posts 20. The mold layer 40 may have a top surface coplanar with those of the posts 20. For example, the mold layer 40 may include an epoxy molding compound (EMC).

The upper substrate 50 may be provided on the posts 20 and the mold layer 40. The upper substrate 50 may include a redistribution substrate. According to an example embodiment, the upper substrate 50 may include second lower pads 52, a warpage control pattern 53, an upper dielectric layer 54, an upper redistribution layer 55, and second upper pads 56.

The second lower pads 52 may be provided on the lower substrate 10 and an edge of the mold layer 40. The second lower pads 52 may be provided on the posts 20 and the mold layer 40 adjacent to the posts 20. When viewed in plan, the second lower pad 52 may be wider than the post 20. The second lower pads 52 may be aligned with the first upper pads 16. The first upper pad 16, the post 20, and the second lower pad 52 may be connected to form an “I” shape when viewed in vertical section. The second lower pad 52 may have a third diameter D3 the same as the first diameter D1 of the first upper pad 16. When viewed in plan, the second lower pad 52 may be wider than the post 20. The third diameter D3 of each second lower pad 52 may be greater than the second diameter D2 of each post 20. For example, the third diameter D3 of the second lower pad 52 may range from about 80 μm to about 450 μm. The third diameter D3 of the second lower pad 52 may be greater, by about 10 μm to about 200 μm, than the second diameter D2 of the post 20. The second lower pad 52 may have a radius greater, by about 5 μm to about 100 μm, than that of the post 20. The second lower pads 52 may cover the posts 20 and boundaries between the posts 20, and may suppress the upper dielectric layer 54 from being cracked due to delamination between the posts 20 and the mold layer 40.

The warpage control pattern 53 may be provided on a center of the mold layer 40. The warpage control pattern 53 may be provided on the lower chip 30. For example, the warpage control pattern 53 may include a plurality of portions, each of which has a width or diameter ranging from about 1 μm to about 30 μm. The warpage control pattern 53 and the second lower pads 52 may have bottom surfaces that are coplanar with that of the upper dielectric layer 54. The warpage control pattern 53 may minimize or prevent warpage of the upper dielectric layer 54.

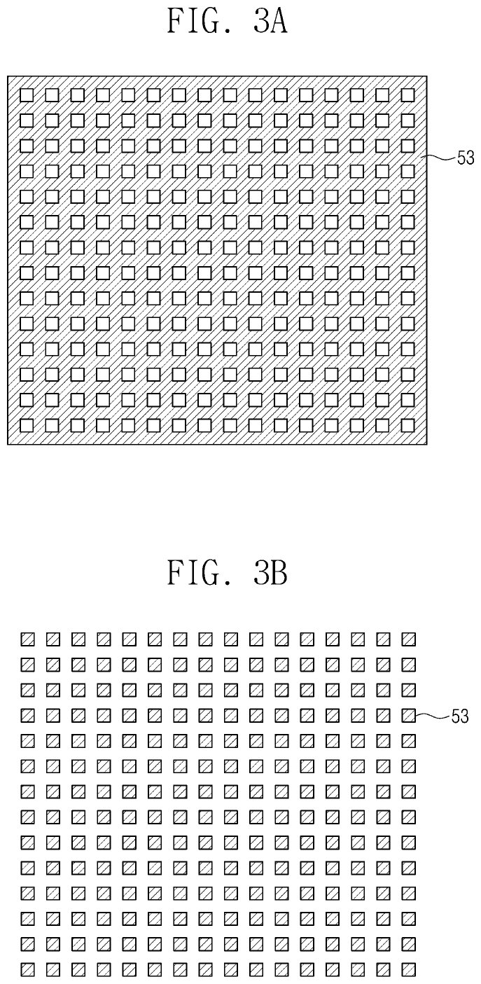

FIG. 3A shows an example of the warpage control pattern 53 depicted in FIG. 2.

Referring to FIG. 3A, the warpage control pattern 53 may have a mesh shape when viewed in plan. Alternatively, the warpage control pattern 53 may have a grating shape, but example embodiments are not limited thereto. For example, each of a plurality of openings defined by the mesh shape or the grating shape may have a width or diameter ranging from about 1 μm to about 30 μm, and portions of the warpage control pattern 53 between the openings may have a width or diameter ranging from about 1 μm to about 30 μm.

FIG. 3B shows an example of the warpage control pattern 53.

Referring to FIG. 3B, the warpage control pattern 53 may have a dot shape. For example, the warpage control pattern 53 may have a tetragonal or circular shape, but example embodiments are not limited thereto. For example, each portion of the warpage control pattern 53 may have a width or diameter ranging from about 1 μm to about 30 μm.

Referring back to FIG. 2, the upper dielectric layer 54 may be provided on the second lower pads 52 and the warpage control pattern 53. The upper dielectric layer 54 may be provided on the mold layer 40. The upper dielectric layer 54 may include the same material as that of the lower dielectric layer 14. For example, the upper dielectric layer 54 may include a photo-imageable dielectric (PID) layer.

The upper redistribution layer 55 may be provided in the upper dielectric layer 54. The upper redistribution layer 55 and the upper dielectric layer 54 may be alternately stacked. The upper redistribution layer 55 may connect the second lower pads 52 to the second upper pads 56. The upper redistribution layer 55 may have a “T” shape when viewed in vertical section. The upper redistribution layer 55 may include copper, but example embodiments are not limited thereto.

The second upper pads 56 may be provided on the upper dielectric layer 54. The second upper pads 56 may be connected to the upper redistribution layer 55. The second upper pads 56 may each have a “T” shape when viewed in vertical section. The second upper pads 56 may include copper, but example embodiments are not limited thereto.

Referring again to FIGS. 1 and 2, the upper package 60 may be provided on the second upper pads 56 and the upper dielectric layer 54. The upper package 60 may have a tetragonal shape when viewed in plan. The upper package 60 may be wider than the lower chip 30. For example, the upper package 60 may include a memory chip. According to an example embodiment, the upper package 60 may be connected to the lower chip 30 through the lower substrate 10, the posts 20, and the upper substrate 50. The upper package 60 may be connected, through second upper bumps 62, to the second upper pads 56 of the upper substrate 50. The second upper bumps 62 may be provided on a second under-fill layer 64.

The following will describe a method of fabricating the package 100 configured above according to example embodiments.

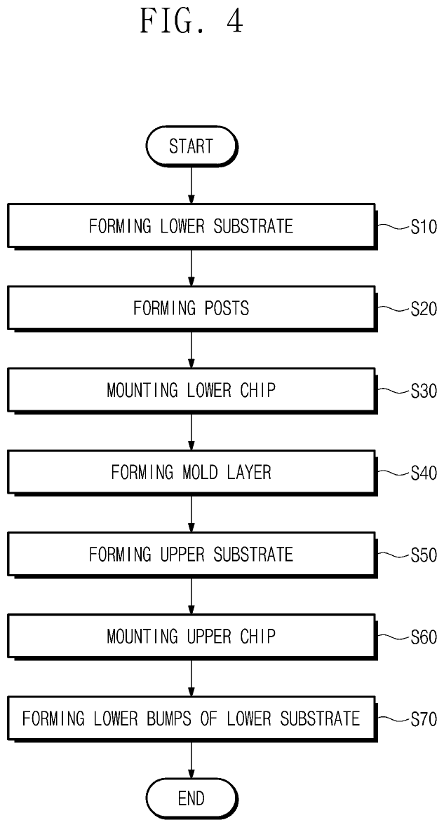

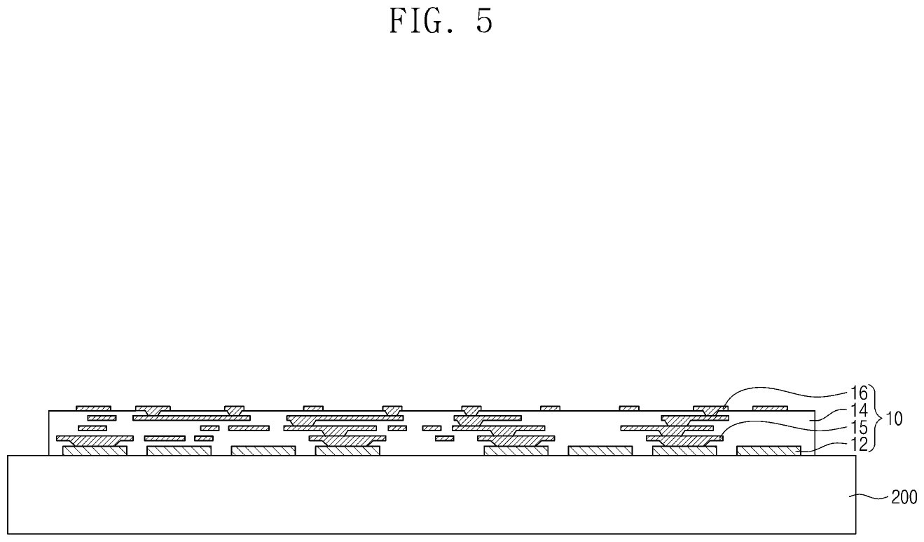

FIG. 4 shows a method of fabricating the package 100 depicted in FIG. 1. FIGS. 5 to 11 are cross-sectional views showing a method of fabricating the package 100 according to some example embodiments.

Referring to FIGS. 4 and 5, a lower substrate 10 may be formed on a dummy substrate 200 (S10). For example, the lower substrate 10 may include a redistribution substrate. The dummy substrate 200 may include a glass substrate or a silicon wafer, but example embodiments are not limited thereto.

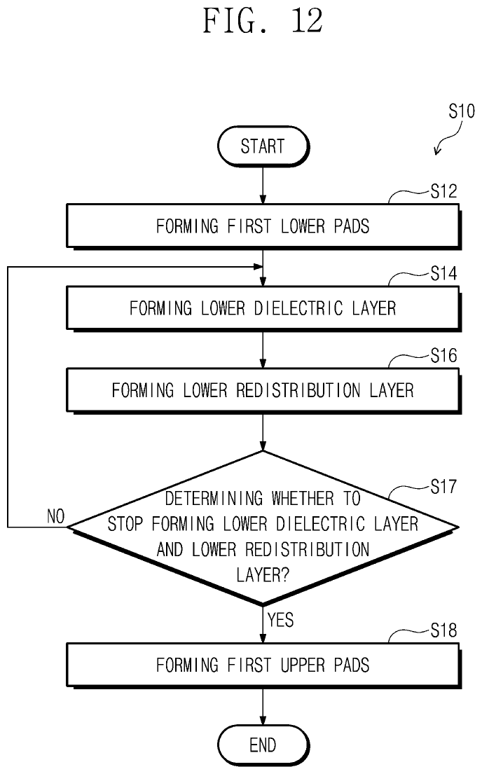

FIG. 12 shows an example of the operation S10 of forming the lower substrate 10.

Referring to FIGS. 5 and 12, first lower pads 12 may be formed on the dummy substrate 200 (S12). The first lower pads 12 may include a metal pattern formed by a film deposition process, a photolithography process, and an etching process. The first lower pads 12 may include gold (Au), silver (Ag), aluminum (Al), tungsten (W), or copper (Cu), but example embodiments are not limited thereto.

A lower dielectric layer 14 may be formed on the first lower pads 12 and the dummy substrate 200 (S14). The lower dielectric layer 14 may be formed by a spin coating process and a photolithography process. For example, the lower dielectric layer 14 may expose portions of the first lower pads 12. The lower dielectric layer 14 may include a photo-imageable dielectric (PID) layer, but example embodiments are not limited thereto.

A lower redistribution layer 15 may be formed on the first lower pads 12 exposed by the lower dielectric layer 14 (S16). The lower redistribution layer 15 may include copper (Cu) formed by an electroplating process. The lower redistribution layer 15 may further include a seed metal, but example embodiments are not limited thereto. The lower redistribution layer 15 may have a “T” shape when viewed in vertical section.

When it is necessary to additionally form the lower dielectric layer 14 and the lower redistribution layer 15 (no in operation S17), the operation S14 and the operation S16 may be repeatedly performed. The lower dielectric layer 14 and the lower redistribution layer 15 may be alternately formed. The lower dielectric layer 14 may be formed on the lower redistribution layer 15, but example embodiments are not limited thereto.

When it is determined to stop forming the lower dielectric layer 14 and the lower redistribution layer 15 (yes in operation S17), first upper pads 16 may be formed on the lower redistribution layer 15 and the lower dielectric layer 14 (S18). The first upper pads 16 may be formed by the same method as that used for forming the lower redistribution layer 15. The first upper pads 16 may include copper (Cu) formed by an electroplating process. Each of the first upper pads 16 may have a first diameter (see D1 of FIG. 1).

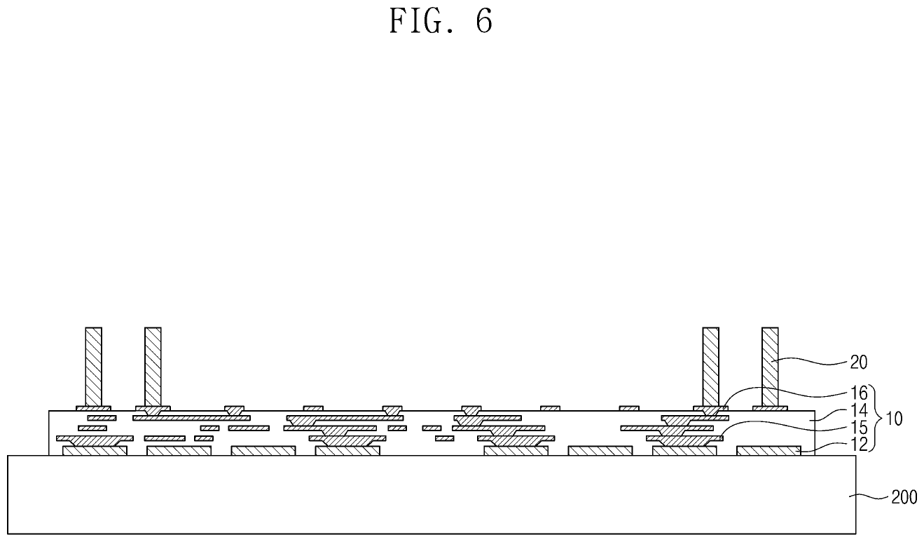

Referring to FIGS. 4 and 6, posts 20 may be formed on the lower substrate 10 (S20). The posts 20 may be formed on the first upper pads 16 of the lower substrate 10. The posts 20 may be formed by an electroplating process, but example embodiments are not limited thereto. The posts 20 may each have a second diameter (see D2 of FIG. 1) less than the first diameter D1 of the first upper pad 16.

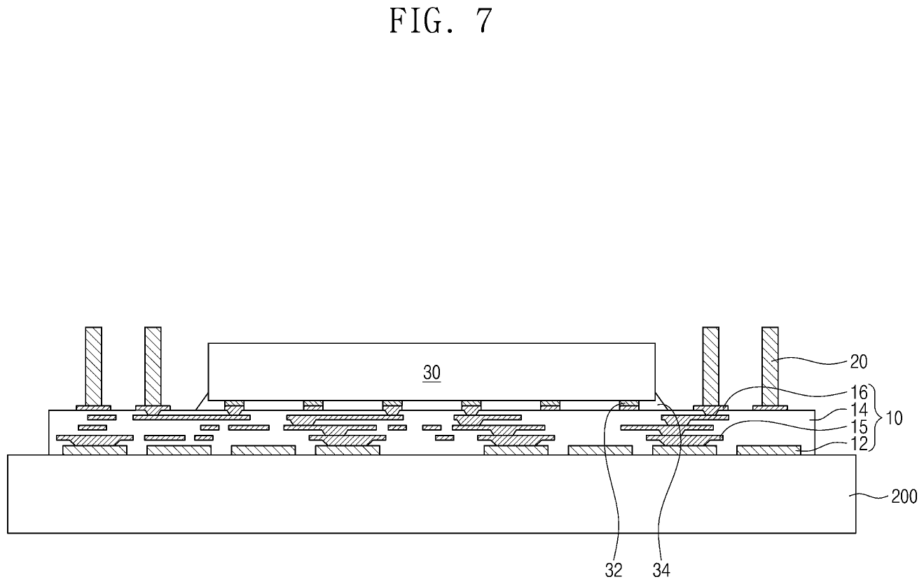

Referring to FIGS. 4 and 7, a lower chip 30 may be mounted on a center of the lower substrate 10 between the posts 20 (S30). The lower chip 30 may be mounted on the center of the lower substrate 10. The lower chip 30 may be connected, through first upper bumps 32, to the first upper pads 16. A first under-fill layer 34 may be provided between the lower chip 30 and the lower substrate 10. The first under-fill layer 34 may protect the first upper pads 16 and the first upper bumps 32 between the lower chip 30 and the lower substrate 10.

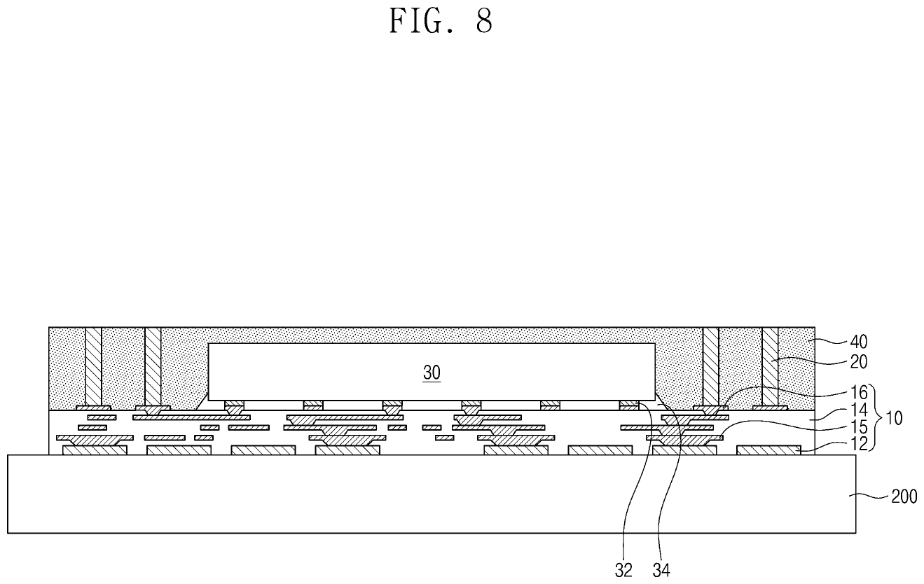

Referring to FIGS. 4 and 8, a mold layer 40 may be formed on the lower chip 30, the lower substrate 10, and sidewalls of the posts (S40). The mold layer 40 may include an epoxy molding compound (EMC). The mold layer 40 may be formed by coating and grinding processes of an epoxy molding compound (EMC). The mold layer 40 may have a top surface coplanar with those of the posts 20.

Referring to FIGS. 3, 9, and 10, an upper substrate 50 may be formed on the second lower pads 52, the warpage control pattern 53, and the mold layer 40 (S50). The upper substrate 50 may include a redistribution substrate.

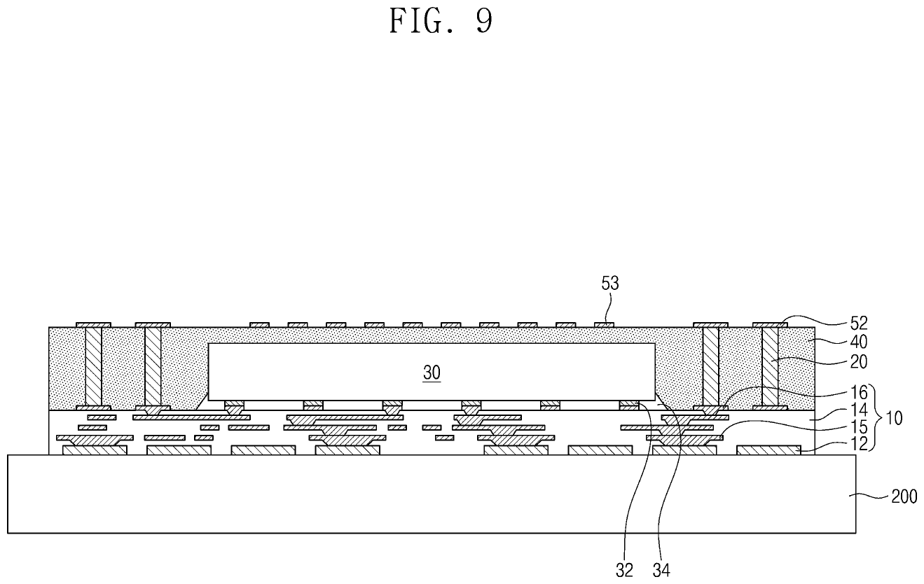

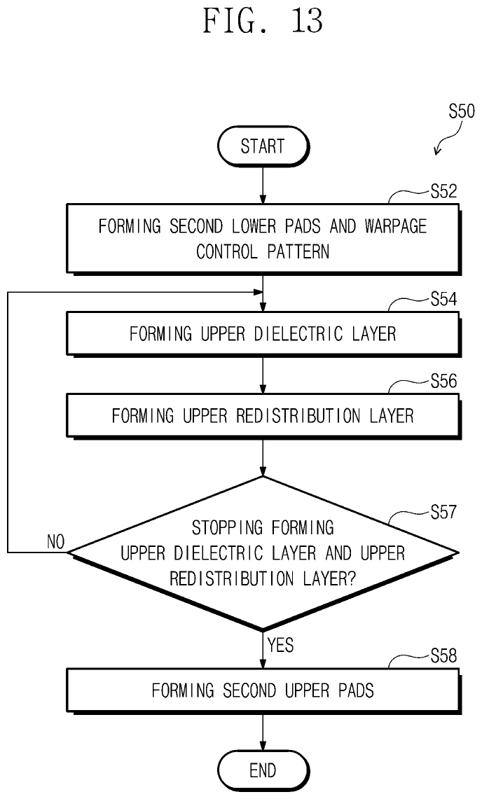

FIG. 13 shows an example of the operation S50 of forming the upper substrate 50 depicted in FIG. 9.

Referring to FIGS. 9 and 13, second lower pads 52 and a warpage control pattern 53 may be formed on the posts 20 and the lower chip 30 (S52). The second lower pads 52 and the warpage control pattern 53 may include metal formed by a film deposition process, a photolithography process, and an etching process. The second lower pads 52 may each have a third diameter (see D3 of FIG. 3) greater than the second diameter D2 of the post 20. The second lower pads 52 may cover boundaries between the posts 20 and the mold layer 40.

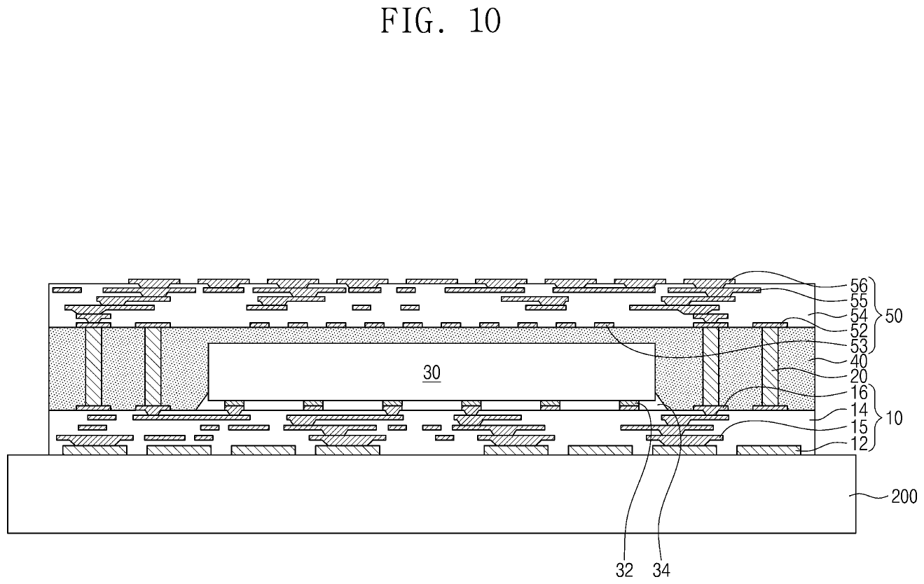

Referring to FIGS. 10 and 13, an upper dielectric layer 54 may be formed on the second lower pads 52, the warpage control pattern 53, and the mold layer 40 (S54). The upper dielectric layer 54 may be formed by a spin coating process and a photolithography process. Additionally, the upper dielectric layer 54 may be cured at high temperatures. For example, the upper dielectric layer 54 may expose portions of the second lower pads 52. The upper dielectric layer 54 may include a photo-imageable dielectric (PID) layer, but example embodiments are not limited thereto. The second lower pads 52 may suppress the upper dielectric layer 54 from being cracked due to delamination between the posts 20 and the mold layer 40 when the upper dielectric layer 54 is cured.

An upper redistribution layer 55 may be formed on the second lower pads 52 exposed by the upper dielectric layer 54 (S56). The upper redistribution layer 55 may include copper (Cu) formed by an electroplating process. The upper redistribution layer 55 may further include a seed metal, but example embodiments are not limited thereto. The lower redistribution layer 15 may have a “T” shape.

When it is necessary to additionally form the upper dielectric layer 54 and the upper redistribution layer 55 (no in operation S57), the operation S54 and the operation S56 may be repeatedly performed. The upper dielectric layer 54 and the upper redistribution layer 55 may be alternately formed. The upper dielectric layer 54 may be formed on the upper redistribution layer 55, but example embodiments are not limited thereto.

When it is determined to stop forming the upper dielectric layer 54 the upper redistribution layer 55 (yes in operation S57), second upper pads 56 may be formed on the upper redistribution layer 55 and the upper dielectric layer 54 (S58). The second upper pads 56 may be formed by the same method as that used for forming the upper redistribution layer 55. The second upper pads 56 may include copper (Cu) formed by an electroplating process.

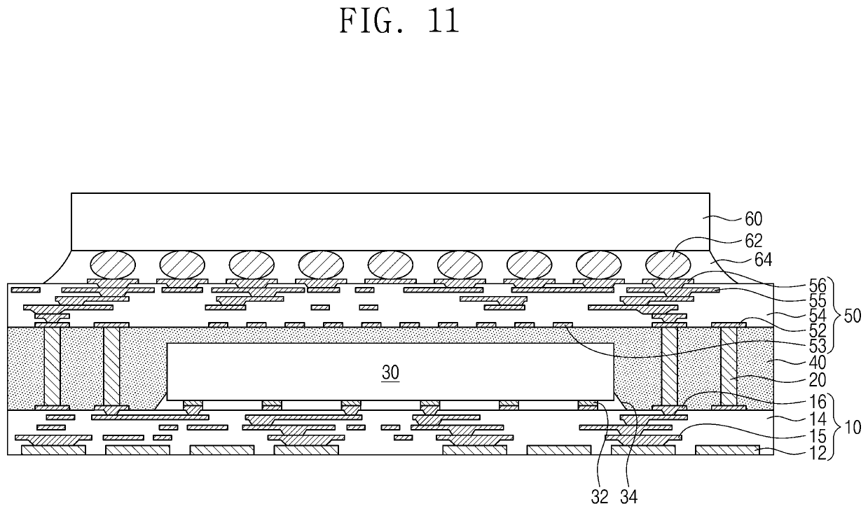

Referring to FIGS. 4 and 11, an upper package 60 may be mounted on the upper substrate 50 (S60). The upper package 60 may include a memory chip. The upper package 60 may be connected, through second upper bumps 62, to the second upper pads 56 of the upper substrate 50. The second upper bumps 62 may be provided in a second under-fill layer 64. The second under-fill layer 64 may rigidly place the upper package 60 on the upper substrate 50.

Afterwards, the dummy substrate 200 may be removed.

Referring to FIGS. 2 and 4, lower bumps 18 may be formed below the first lower pads 12 of the lower substrate 10 (S70). The lower bumps 18 may be electrically connected to the lower chip 30 and the upper package 60. The lower bumps 18 may connect the lower chip 30 and the upper package 70 to an external substrate or an external device.

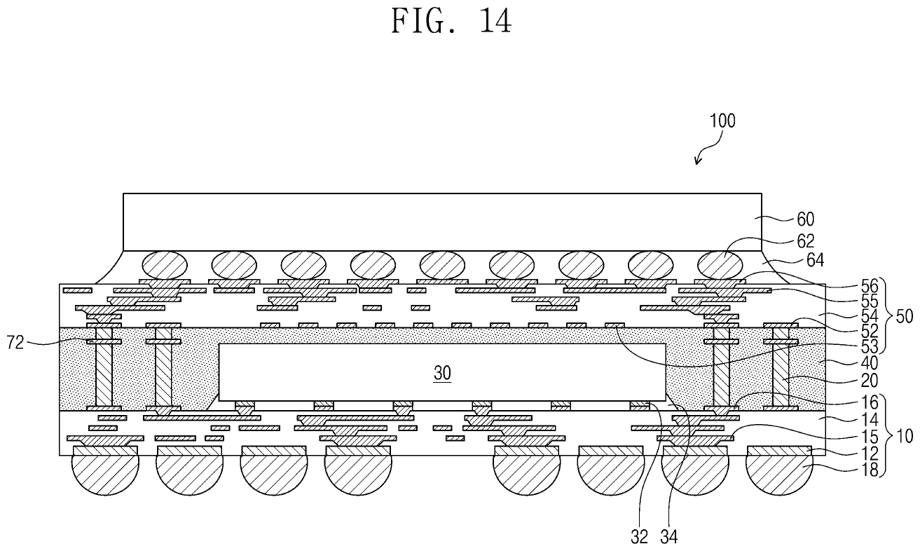

FIG. 14 shows an example of the package 100 according to example embodiments.

Referring to FIG. 14, the package 100 according to example embodiments may further include intermediate pads 72. The intermediate pads 72 may be connected to the posts 20 below the second lower pads 52. The intermediate pads 72 may be parallel to the second lower pads 52. The intermediate pads 72 may be aligned with the second lower pads 52. The intermediate pads 72 may have their bottom surfaces aligned with a top surface of the lower chip 30. The post 20, the second lower pad 52, and the intermediate pad 72 may be connected to form a “ [symbol] ” shape when viewed in vertical section. The intermediate pads 72 may increase in boundary areas between the posts 20 and the mold layer 40 and minimize or prevent delamination between the posts 20 and the mold layer 40.

The lower substrate 10, the posts 20, the lower chip 30, the mold layer 40, the upper substrate 50, and the upper package 60 may be configured identically to those depicted in FIG. 2.

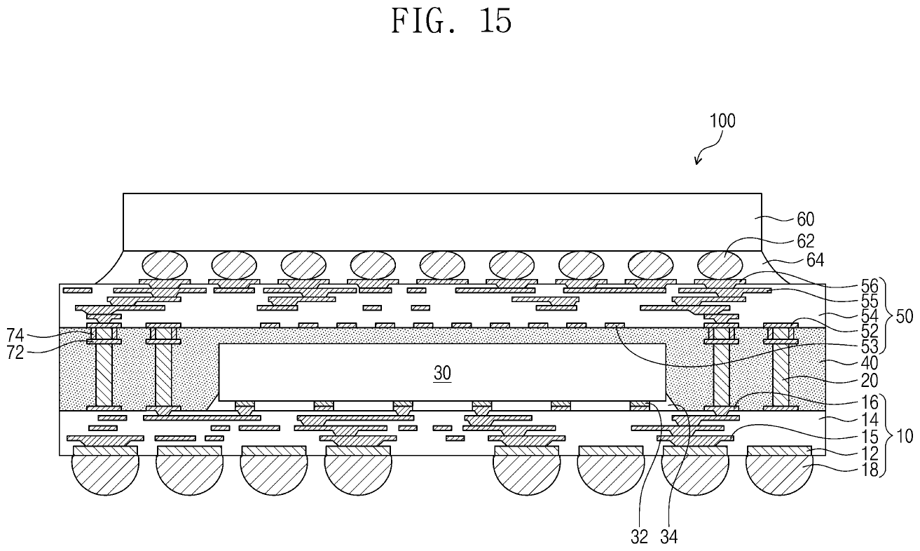

FIG. 15 shows an example of the package 100 according to example embodiments.

Referring to FIG. 15, the package 100 may include shields 74. The shields 74 may be provided between the intermediate pads 72 and the second lower pads 52. The posts 20 may have their upper portions between the intermediate pads 72 and the second lower pads 52, and the posts 20 may surround the upper portions of the posts 20. The shields 74 may be provided between the posts 20 and the mold layer 40. The shields 74 may increase outer diameters of the posts 20 and minimize or prevent delamination between the mold layer 40 and the posts 20. In addition, the shields 74 may increase adhesive forces between the posts 20 and the mold layer 40, and may decrease contact areas between the posts 20 and the mold layer 40. Therefore, shields 74 may suppress the upper dielectric layer 54 from being cracked due to delamination between the posts 20 and the mold layer 40. For example, the shields 74 may include a polymer or a dielectric.

The lower substrate 10, the posts 20, the lower chip 30, the mold layer 40, the upper substrate 50, and the upper package 60 may be configured identically to those depicted in FIG. 2.

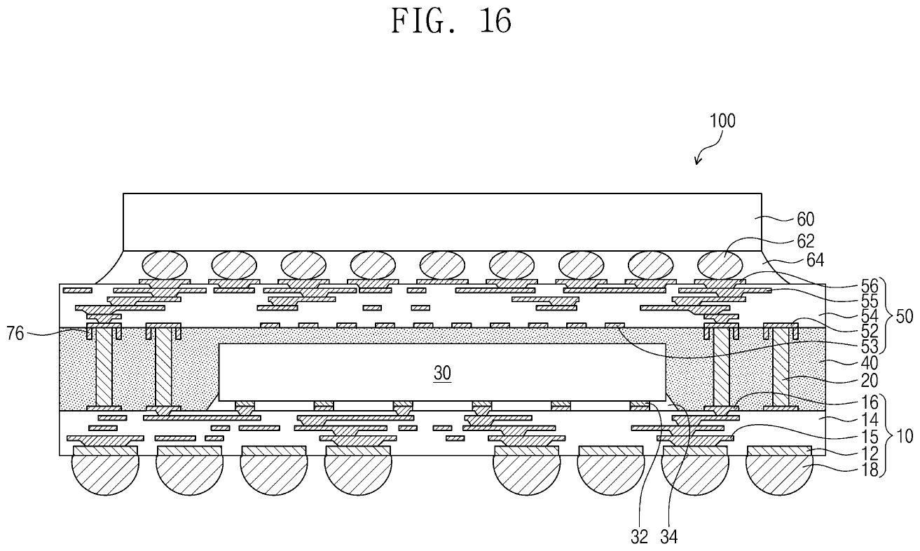

FIG. 16 shows an example of the package 100 according to example embodiments.

Referring to FIG. 16, the package 100 may be configured such that the second lower pads 52 have tails 76. When viewed in vertical section, the tails 76 may be provided below edges of the second lower pads 52. The tail 76, the second lower pad 52, and the post 20 may be connected to form a “T” shape when viewed in vertical section. The tails 76 may increase contact areas between mold layer 40 and the second lower pads 52, and may suppress a crack of the upper dielectric layer 54 on the second lower pads 52. For example, tail 76 may have a ring shape when viewed in plan. The post 20 may be disposed in the tail 76. For example, the tails 76 may surround contours of upper portions of the posts 20.

The lower substrate 10, the posts 20, the lower chip 30, the mold layer 40, the upper substrate 50, and the upper package 60 may be configured identically to those depicted in FIG. 2.

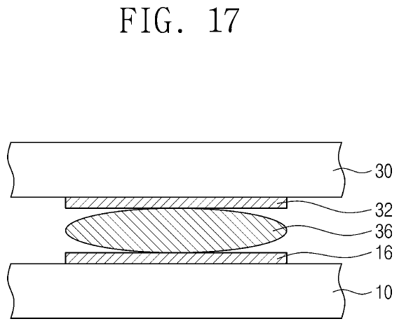

FIG. 17 shows examples of the first upper pad 16, the first upper bump 32, and a solder 36 of FIG. 2.

Referring to FIG. 17, the solder 36 may be provided between the first upper pad 16 and the first upper bump 32. For example, the solder 36 may include Sn—Pb, Pb—Sn, Sn—Pb—Bi, Bi—Sn, Sn—Pb—Ag, Sn—Ag, Sn—Sb, Pb—Ag, or Pb—Ag—Sn. The first upper pad 16 may include a hetero-metal stack of Cu/Ni/Au. For example, a seed metal may be provided between the first upper pad 16 and the post (see 20 of FIG. 1). The seed metal may include titanium (Ti) or copper (Cu).

As discussed above, a package according to some example embodiments may include an upper substrate having upper pads wider than posts, and the upper substrate may be used to suppress a crack of the upper substrate on a lower chip.

While aspects of example embodiments have been particularly shown and described, it will be understood that various changes in form and details may be made therein without departing from the spirit and scope of the following claims.

What is claimed is:

1. A package, comprising:
a lower substrate comprising an upper pad;
a lower chip on the lower substrate;
a mold layer on the lower chip and the lower substrate;
a post extending through the mold layer and provided on the upper pad around the lower chip, the post having a diameter less than a diameter of the upper pad; and
an upper substrate on the post and the mold layer, the upper substrate comprising a lower pad having a diameter greater than the diameter of the post.

2. The package of claim 1, wherein the upper pad and the lower pad have a common diameter.

3. The package of claim 1, wherein the upper pad, the post, and the lower pad are connected to form an “I” shape when viewed in vertical section.

4. The package of claim 1, wherein the diameter of the lower pad is greater by 10 μm to 20 μm than the diameter of the post.

5. The package of claim 1, wherein the lower substrate further comprises a lower redistribution layer connected to the upper pad,
wherein the upper substrate further comprises an upper redistribution layer connected to the lower pad, and
wherein each of the lower redistribution layer and the upper redistribution layer has a “T” shape.

6. The package of claim 1, further comprising an intermediate pad on a middle portion of the post,
wherein the post, the lower pad, and the intermediate pad are connected to form a “ [symbol] ” shape when viewed in vertical section.

7. The package of claim 6, further comprising a shield between the intermediate pad and the lower pad.

8. The package of claim 7, wherein the post is in the shield.

9. The package of claim 1, wherein the lower pad has a tail that surrounds the post.

10. The package of claim 9, wherein the post, the lower pad, and the tail are connected to form a “T” shape when viewed in vertical section.

11. A package, comprising:
a lower substrate comprising an upper pad;
a lower chip on the lower substrate;
a post on the upper pad, the post having a diameter less than a diameter of the upper pad; and
an upper substrate on the post, the upper substrate comprising a lower pad having a diameter greater than the diameter of the post,
wherein the upper pad, the post, and the lower pad are connected to form an “I” shape when viewed in vertical section.

12. The package of claim 11, further comprising an intermediate pad on a middle portion of the post,
wherein the post, the lower pad, and the intermediate pad are connected to form a “ [symbol] ” shape when viewed in vertical section.

13. The package of claim 12, further comprising a shield between the intermediate pad and the lower pad,
wherein the post is provided in the shield.

14. The package of claim 11, wherein the lower pad has a tail that surrounds a contour of the post, and
wherein the post, the lower pad, and the tail are connected to form a “ [symbol] ” shape when viewed in vertical section.

15. The package of claim 11, wherein the lower substrate further comprises a lower redistribution layer connected to the upper pad,
wherein the upper substrate further comprises an upper redistribution layer connected to the lower pad, and
wherein each of the lower redistribution layer and the upper redistribution layer has a “T” shape.

16. A method of fabricating a package, the method comprising:
providing a lower substrate having upper pads on a dummy substrate, the upper pads each having a diameter;
providing posts on the upper pads, the posts each having a diameter less than the diameter of the upper pads;
providing a lower chip on the lower substrate between the posts;
providing a mold layer on the lower substrate that selectively exposes top surfaces of the posts; and
providing an upper substrate that is on the posts and the mold layer, and has lower pads, each having a diameter greater than the diameter of the posts.

17. The method of claim 16, wherein the lower pads and the upper pads have a common diameter.

18. The method of claim 16, wherein the providing the lower substrate comprises:
providing first lower pads on the dummy substrate;
providing a lower dielectric layer on the first lower pads; and
providing a lower redistribution layer in the lower dielectric layer.

19. The method of claim 18, wherein the providing the upper substrate comprises:
providing second lower pads and a warpage control pattern on the posts and the mold layer;
providing an upper dielectric layer on the second lower pads, the warpage control pattern, and the mold layer; and
providing an upper redistribution layer in the upper dielectric layer.

20. The method of claim 19, wherein each of the lower redistribution layer and the upper redistribution layer has a “T” shape when viewed in plan.
